(19) United States
(12) Patent Application Publication
(10) Pub. No.: US 2026/0150381 A1
(43) Pub. Date: May 28, 2026

(54) SEMICONDUCTOR DEVICE AND METHOD MANUFACTURING THE SAME

(71) Applicant: SAMSUNG ELECTRONICS CO., LTD., Suwon-si (KR)

(72) Inventors: Jiwon KANG, Suwon-si (KR); Wandon KIM, Suwon-si (KR); Geunwoo KIM, Suwon-si (KR); Sungrok PARK, Suwon-si (KR)

(73) Assignee: SAMSUNG ELECTRONICS CO., LTD., Suwon-si (KR)

(21) Appl. No.: 19/224,093

(22) Filed: May 30, 2025

(30) Foreign Application Priority Data
Nov. 25, 2024 (KR) 10-2024-0169881

(51) Int. Cl. H10D 84/01; H01L 21/768; H10D 30/00; H10D 30/01; H10D 62/10; H10D 62/13; H10D 64/23; H10D 64/62; H10D 84/83

(52) U.S. Cl. CPC H10D 84/0149; H10D 30/0191; H10D 64/256; H10D 64/62; H10D 84/013; H10W 20/039; H10W 20/054; H10W 20/056; H10W 20/065; H10D 30/503; H10D 30/506; H10D 62/121; H10D 62/151; H10D 84/832

(57) ABSTRACT

A method of manufacturing a semiconductor device, includes: forming a source/drain region; forming an interlayer insulating layer on the source/drain region; forming a contact hole by removing at least a portion of the interlayer insulating layer to expose the source/drain region; forming a metal-semiconductor compound layer in the contact hole to be connected to the source/drain region; forming a liner conductive layer on the metal-semiconductor compound layer; and oxidizing the liner conductive layer; removing an oxidized portion of the liner conductive layer; and forming a contact conductive layer on the liner conductive layer.

### CROSS-REFERENCE TO RELATED APPLICATION(S)

This application claims benefit of priority to Korean Patent Application No. 10-2024-0169881 filed on Nov. 25, 2024 in the Korean Intellectual Property Office, the disclosure of which is incorporated herein by reference in its entirety.

### BACKGROUND

The present disclosure relates to a semiconductor device and a method for manufacturing the same.

As demand for high performance, high speed, and/or multifunctionality of semiconductor devices increases, a degree of integration of semiconductor devices is also increasing. In manufacturing a semiconductor device with a fine pattern corresponding to the trend of a high degree of integration of semiconductor devices, it is required to implement patterns having a fine width or a fine separation distance. In addition, efforts are being made to develop a semiconductor device including a transistor having a three-dimensional channel structure in order to overcome limitations of operating characteristics due to a decrease in size of a planar metal oxide semiconductor field-effect transistor (MOSFET).

### SUMMARY

Various aspects of the disclosure provide a semiconductor device having an improved degree of integration and improved reliability, and also provide a method for manufacturing a semiconductor device having reduced process difficulty and reduced process costs.

According to an aspect of the disclosure, there is provided a method for manufacturing a semiconductor device. The method may include: forming a source/drain region; forming an interlayer insulating layer on the source/drain region; forming a contact hole by removing at least a portion of the interlayer insulating layer to expose the source/drain region; forming a metal-semiconductor compound layer in the contact hole to be connected to the source/drain region; forming a liner conductive layer on the metal-semiconductor compound layer; oxidizing the liner conductive layer; removing an oxidized portion of the liner conductive layer; forming a preliminary contact conductive layer on the liner conductive layer; forming a sacrificial metal layer on the preliminary contact conductive layer; removing the sacrificial metal layer and a portion of the preliminary contact conductive layer using a planarization process; and forming a contact conductive layer by heat treating the preliminary contact conductive layer using hydrogen plasma.

According to an aspect of the disclosure, there is provided a method for manufacturing a semiconductor device. The method may include: forming a semiconductor region on a substrate and forming an interlayer insulating layer on the semiconductor region; removing a portion of the interlayer insulating layer to form a contact hole exposing the semiconductor region; forming a metal-semiconductor compound layer on a lower end of the contact hole to be connected to the semiconductor region; forming a liner conductive layer on the metal-semiconductor compound layer; forming a preliminary contact conductive layer on the liner conductive layer; and forming a contact conductive layer by heat-treating the preliminary contact conductive layer such that a size of a crystal grain of the contact conductive layer is greater than a size of a crystal grain of the preliminary contact conductive layer.

According to an aspect of the disclosure, there is provided a method for manufacturing a semiconductor device. The method may include: forming a source/drain region and an interlayer insulating layer on the source/drain region; removing a portion of the interlayer insulating layer to form a contact hole exposing the source/drain region; forming a metal-semiconductor compound layer on a lower end of the contact hole; forming a liner conductive layer on the metal-semiconductor compound layer; removing a portion of the liner conductive layer; and forming a contact conductive layer on the liner conductive layer, wherein the liner conductive layer is formed such that the liner conductive layer has a first thickness on a side surface of the contact conductive layer, and a second thickness, greater than the first thickness, on a bottom surface of the contact conductive layer.

According to an aspect of the disclosure, there is provided a semiconductor device which may include: a source/drain region, an interlayer insulating layer with a contact hole exposing the source/drain region, and a contact plug formed in the contact hole and connecting the source/drain region to a voltage source or another circuit element, wherein the contact plug includes a metal-semiconductor compound layer in the contact hole to be connected to the source/drain region; a liner conductive layer on the metal-semiconductor compound layer; forming a preliminary contact conductive layer on the liner conductive layer; forming a sacrificial metal layer on the preliminary contact conductive layer; removing the sacrificial metal layer and a portion of the preliminary contact conductive layer using a planarization process; and heat-treating the preliminary contact conductive layer using hydrogen plasma to form a contact conductive layer. The liner conductive layer may have a thickness which varies along an inner profile of the contact hole. The liner conductive layer may have a thickness which varies along an inner profile of the contact hole. No nitride may be formed between the contact conductive layer and the interlayer insulating layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to one or more embodiments.

FIG. 2 is a cross-sectional view illustrating a semiconductor device according to one or more embodiments.

FIG. 3 is a partially enlarged view illustrating a semiconductor device according to one or more embodiments.

FIG. 4 is a cross-sectional view illustrating a semiconductor device according to one or more embodiments.

FIG. 5 is a cross-sectional view illustrating a semiconductor device according to one or more embodiments.

FIG. 6 is a cross-sectional view illustrating a semiconductor device according to one or more embodiments.

FIGS. 7A to 7N are views illustrating a process sequence illustrating a method of manufacturing a semiconductor device according to one or more embodiments.

FIG. 8 is a schematic process flow diagram illustrating a method of manufacturing a semiconductor device according to one or more embodiments.

### DETAILED DESCRIPTION

The embodiments described herein are non-limiting example embodiments, and thus, the disclosure is not limited thereto and may be realized in various other forms. Each of the embodiments provided herein is not excluded from being associated with one or more features of another example or another embodiment also provided herein or not provided herein but consistent with the disclosure. For example, even if matters described in a specific example or embodiment are not described in a different example or embodiment, the matters may be understood as being related to or combinable with the different example or embodiment, unless otherwise mentioned in descriptions thereof. In addition, it should be understood that all descriptions of principles, aspects, examples, and specific embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present

Spatially relative terms, such as “over,” “above,” “on,” “upper,” “below,” “under,” “beneath,” “lower,” “left,” “right,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 5% or less than the stated amount.

It will be understood that, when the term “contact” is used to describe two metal componets, for example, a metal line and a via structure, a barrier metal layer such as titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contract structure is described as being formed on or contact a surface of a source/drain region, a silicide layer such as cobalt silicide (CoSi₂), nickel silicide (NiSi₂), titanium silicide (TiSi₂ or TiSi₂), or tungsten silicide (WSi₂), not being limited thereto, may be formed therebetween.

In addition, ordinal numbers such as “first,” “second,” “third,” and the like may be used as labels for specific elements, operations, directions, or the like to distinguish various elements, operations, directions, or the like. Terms not described using “first,” “second,” and the like in the specification may still be referred to as “first” or “second” in the claims. In addition, terms referenced by a specific ordinal number (e.g., “first” in a specific claim) may be described elsewhere with a different ordinal number (e.g., “second” in the specification or another claim).

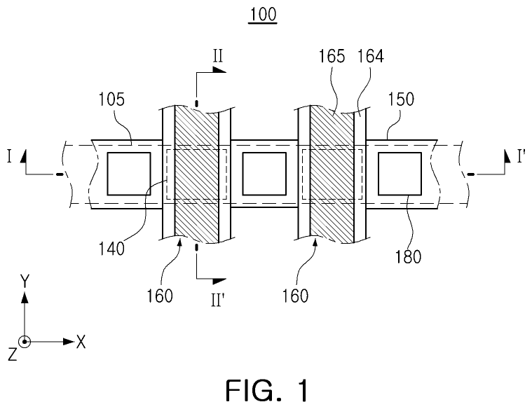

FIG. 1 is a plan view illustrating a semiconductor device according to one or more embodiments.

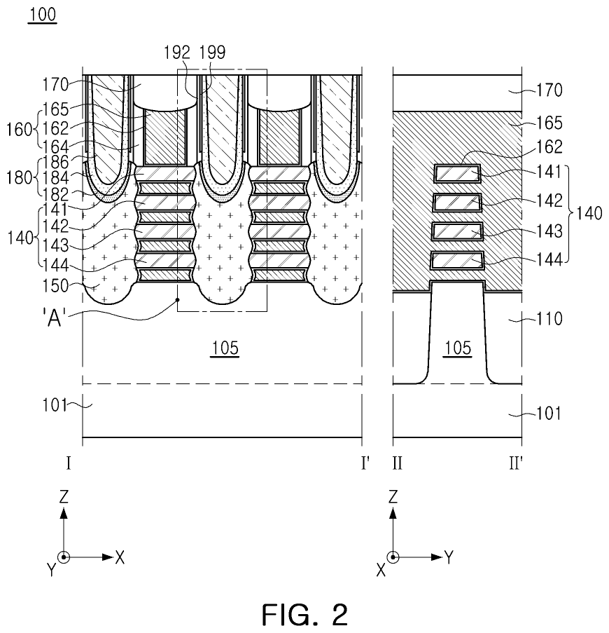

FIG. 2 is a cross-sectional view illustrating a semiconductor device according to one or more embodiments. FIG. 2 illustrates cross-sections of the semiconductor device of FIG. 1, taken along lines I-I′ and II-II'. For convenience of explanation, only some components of the semiconductor device are illustrated in FIG. 1.

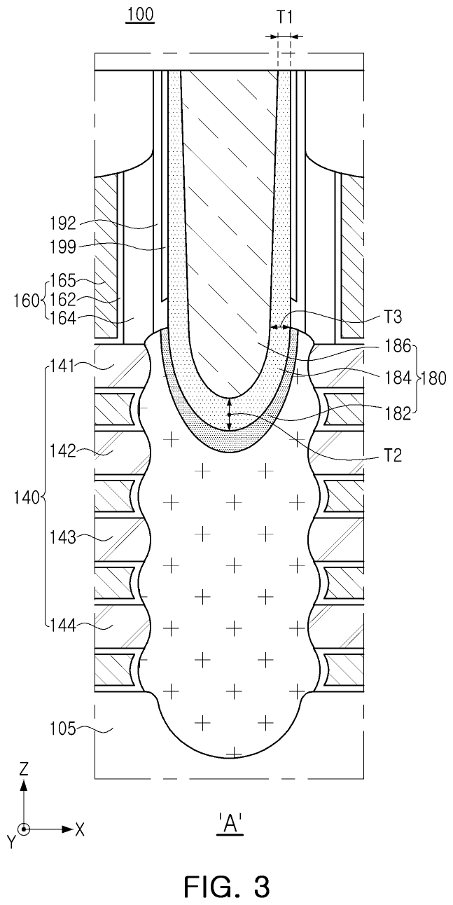

FIG. 3 is a partially enlarged view illustrating a semiconductor device according to one or more embodiments. FIG. 3 illustrates an enlarged view of portion ‘A’ of FIG. 2.

Referring to FIGS. 1 to 3, a semiconductor device 100 may include a substrate 101 including an active region 105, channel structures 140 including first to fourth channel layers 141, 142, 143, and 144 disposed to be vertically spaced apart on the active region 105, gate structures 160 extending across the active region 105 and respectively including gate electrodes 165, source/drain regions 150 on the channel structures 140, and contact plugs 180 on the source/drain regions 150. The semiconductor device 100 may further include a device isolation layer 110, gate capping layers 170, insulating liner layers 192, and an interlayer insulating layer 199.

In the semiconductor device 100, the active region 105 may have a fin structure, and the gate electrode 165 may be disposed between the active region 105 and a channel structure 140, between the first to fourth channel layers 141, 142, 143, and 144 of the channel structure 140, and on the channel structure 140. Therefore, the semiconductor device 100 may include transistors having a MBCFET™ (Multi Bridge Channel FET) structure, which may be a gate-all-around type field effect transistor.

The substrate 101 may have an upper surface extending in an X-direction and a Y-direction. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, a semiconductor on insulator (SeOI) layer, or the like.

The substrate 101 may include the active region 105 disposed in an upper portion. The active region 105 may be defined by the device isolation layer 110 in the substrate 101, and may be disposed to extend in a first direction, for example, the X-direction. Depending on a description method, it is also possible to describe the active region 105 as a separate configuration from the substrate 101. The active region 105 may partially protrude above the device isolation layer 110, such that an upper surface of the active region 105 may be at a higher level than an upper surface of the device isolation layer 110. The active region 105 may be formed as a portion of the substrate 101 or may include an epitaxial layer grown from the substrate 101. At both sides of the gate structure 160, the active region 105 may be partially recessed to form recess regions, and source/drain regions 150 may be disposed in the recess regions.

In one or more embodiments, the active region 105 may or may not include a well region including impurities. For example, in a p-type transistor (pFET), the well region may include n-type impurities such as phosphorus (P), arsenic (As), or antimony (Sb), and in an n-type transistor (nFET), the well region may include p-type impurities such as boron (B), gallium (Ga), or indium (In). The well region may be disposed at a predetermined depth from the upper surface of the active region 105, for example.

The device isolation layer 110 may define the active region 105 in the substrate 101. The device isolation layer 110 may be formed, for example, by a shallow trench isolation (STI) process. The device isolation layer 110 may expose the upper surface of the active region 105, and may also expose an upper portion. In some embodiments, the device isolation layer 110 may have a curved upper surface such that it has a higher level as it approaches the active region 105. The device isolation layer 110 may be formed of an insulating material. The device isolation layer 110 may be, for example, an oxide, a nitride, or a combination thereof.

The gate structures 160 may be disposed on the active region 105 and the channel structures 140, to extend in a second direction, for example, the Y-direction, intersecting the active region 105 and the channel structures 140. Functional channel regions of the transistors may be formed in the active region 105 and/or the channel structures 140 intersecting the gate electrodes 165 of the gate structures 160. Each of the gate structures 160 may include a gate electrode 165, gate dielectric layers 162 between the gate electrode 165 and the first to fourth channel layers 141, 142, 143, and 144, and gate spacer layers 164 on side surfaces of the gate electrode 165.

The gate dielectric layers 162 may be disposed between the active region 105 and the gate electrode 165 and between the channel structure 140 and the gate electrode 165, and may be disposed to be on at least a portion of surfaces of the gate electrode 165. For example, the gate dielectric layers 162 may be disposed to surround all surfaces except an uppermost surface of the gate electrode 165. The gate dielectric layers 162 may extend between the gate electrode 165 and the gate spacer layers 164, but is not limited thereto. The gate dielectric layers 162 may include an oxide, a nitride, or a high-κ material. The high-κ material may mean a dielectric material having a higher dielectric constant than a silicon oxide (SiO₂). The high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). According to embodiments, the gate dielectric layer 162 may be formed as a multilayer film.

The gate electrode 165 may be disposed to fill spaces between the first to fourth channel layers 141, 142, 143, and 144 on the active region 105, and to extend onto the channel structure 140. The gate electrode 165 may be separated from the first to fourth channel layers 141, 142, 143, and 144 by the gate dielectric layers 162. The gate electrode 165 may include a conductive material, and may include, for example, a metal nitride such as a titanium nitride (TiN), a tantalum nitride (TaN), or a tungsten nitride (WN), and/or a metal material such as aluminum (Al), tungsten (W), molybdenum (Mo), or the like, or a semiconductor material such as doped polysilicon. According to embodiments, the gate electrode 165 may be formed as two or more multilayers.

The gate spacer layers 164 may be disposed on both side surfaces of the gate electrode 165 on the channel structure 140. The gate spacer layers 164 may insulate the source/drain regions 150 and the gate electrode 165. The gate spacer layers 164 may be formed as a multilayer structure, according to embodiments. The gate spacer layers 164 may be formed of at least one of an oxide, a nitride, or an oxynitride, and may be formed as, for example, a low-κ film.

The channel structures 140 may be disposed on the active region 105 in regions in which the active region 105 intersects the gate structures 160. Each of the channel structures 140 may include a plurality of channel layers, e.g., the first to fourth channel layers 141, 142, 143, and 144, which may be disposed to be spaced apart in a Z-direction. The first to fourth channel layers 141, 142, 143, and 144 may be sequentially disposed from an upper portion of the semiconductor device 100, and the first channel layer 141 may be an uppermost channel layer. The channel structures 140 may be connected to the source/drain regions 150. The channel structures 140 may have a width, equal or similar to a width of the gate structures 160 in the X-direction, and may have a width, equal to or smaller than a width of the active region 105 in the Y-direction. In a cross-section in the Y-direction, a channel layer disposed in a lower portion, among the first to fourth channel layers 141, 142, 143, and 144, may have a width, equal to or larger than a width of a channel layer disposed in an upper portion. The number and shapes of channel layers forming one channel structure 140 may change according to embodiments. For example, a single channel structure 140 may include three channel layers, two channel layers, or five or more channel layers.

The channel structures 140 may be formed of a semiconductor material, for example, at least one of silicon (Si), silicon germanium (SiGe), or germanium (Ge). The channel structures 140 may be formed of, for example, the same material as the active region 105. In one or more other embodiments, the channel structures 140 may include an impurity region adjacent to the source/drain regions 150.

The source/drain regions 150 may be disposed in recess regions partially recessing an upper portion of the active region 105 at both sides of the gate structure 160. The recess regions may extend along side surfaces of the channel structures 140 and side surfaces of the gate dielectric layers 162. The source/drain regions 150 may be disposed to be on side surfaces of each of the first to fourth channel layers 141, 142, 143, and 144 of the channel structures 140 in the X-direction. Upper surfaces of the source/drain regions 150 may be at a level, equal to or higher than lower surface of the gate electrodes 165 on the channel structures 140, and the level may be variously changed according to embodiments. Side surfaces of the source/drain regions 150 may have a curvature according to the first to fourth channel layers 141, 142, 143, and 144 and the gate structure 160. Specific shapes of the side surfaces of the source/drain regions 150 may be variously changed according to embodiments.

The source/drain regions 150 may include a semiconductor material, for example, at least one of silicon (Si) or germanium (Ge), and may further include dopants. For example, when the semiconductor device 100 is a pFET, the dopants may be at least one of boron (B), gallium (Ga), or indium (In). The source/drain regions 150 may be formed as an epitaxial layer.

The gate capping layers 170 may be respectively disposed on the gate structures 160. The insulating liner layers 192 may be on side surfaces of the gate capping layers 170 and outer side surfaces of the gate spacer layers 164, and may be folded and extend onto upper surfaces of the source/drain regions 150. The gate capping layers 170, the insulating liner layers 192, and the interlayer insulating layer 199 may include at least one of an oxide, a nitride, or an oxynitride, respectively. The interlayer insulating layer 199 may be formed to fill a space between sacrificial gate structures 200 on the insulating liner layers 192. The interlayer insulating layer 199 may include at least one of an oxide, a nitride, or an oxynitride, and may include, for example, a low-κ material. In one or more other embodiments, the insulating liner layers 192 may be omitted. In one or more other embodiments, the interlayer insulating layer 199 may include a plurality of insulating layers.

The contact plugs 180 may penetrate the insulating liner layers 192, may be connected to the source/drain regions 150, and may apply an electrical signal to the source/drain regions 150. The contact plugs 180 may recess the source/drain regions 150, and may extend into the source/drain regions 150. Lower ends of the contact plugs 180 may be, for example, at a level between a lower surface of the first channel layer 141 and an upper surface of the third channel layer 143.

The contact plug 180 may include a metal-semiconductor compound layer 182 in a lower portion, a liner conductive layer 184 on the metal-semiconductor compound layer 182, and a contact conductive layer 186 filling an internal space of the contact plug 180.

The metal-semiconductor compound layer 182 may be in contact with the source/drain regions 150. The metal-semiconductor compound layer 182 may be disposed along a recessed surface of the source/drain regions 150. A lower end of the metal-semiconductor compound layer 182 may correspond to a lower end of the contact plug 180. The metal-semiconductor compound layer 182 may have an uneven thickness along a surface of the source/drain region 150. In this case, the ‘thickness’ may mean a dimension in a direction, locally perpendicular to the recessed surface of the source/drain region 150. The metal-semiconductor compound layer 182 may have, for example, a shape in which the thickness increases toward the lower end of the contact plug 180. The metal-semiconductor compound layer 182 may have a thickness in a range of about 1 nm to 4 nm. The metal-semiconductor compound layer 182 may include a metal element and a semiconductor element, and may include, for example, cobalt silicide (CoSi₂), nickel silicide (NiSi₂), titanium silicide (TiSi or TiSi₂), or tungsten silicide (WSi₂), which may be referred to as a silicide layer. Alternatively, the metal-semiconductor compound layer 182 may include germanium (Ge), in addition to or instead of silicon (Si).

The contact conductive layer 186 may be on the liner conductive layer 184 to fill a region in which the source/drain region 150 is recessed, and may extend to an upper portion of the contact plug 180. The contact conductive layer 186 may have a shape in which a width nonlinearly decreases toward the source/drain region 150. The contact conductive layer 186 may include a metal material such as, for example, tungsten (W), molybdenum (Mo), or the like.

The liner conductive layer 184 may be between the metal-semiconductor compound layer 182 and the contact conductive layer 186. The liner conductive layer 184 may be interposed between the metal-semiconductor compound layer 182 and the contact conductive layer 186 in a lower portion, and may surround a side surface of the contact conductive layer 186 in an upper portion. The liner conductive layer 184 may include only a metal element, for example, without including nitride (N), may not include titanium (Ti) and tantalum (Ta), and may include at least one of tungsten (W) or molybdenum (Mo), which may be the same as or different from the metal material forming the contact conductive layer 186.

Resistivity of the contact conductive layer 186 may be in a range of about 9 μΩcm to about 18 μΩcm, and resistivity of the liner conductive layer 184 may be in a range of about 10 μΩcm to about 20 μΩcm. Therefore, a ratio of the resistivity of the liner conductive layer 184 to the resistivity of the contact conductive layer 186 may be in a range of about 0.45 to about 1.8.

Referring to FIG. 3, a side region of the liner conductive layer 184 extending along a side surface of the contact conductive layer 186 may have a thickness increasing toward the source/drain region. The liner conductive layer 184 may have a first thickness T1 and a third thickness T3 on a side surface of the contact conductive layer 186, and may have a second thickness T2, greater than the first thickness T1 and the third thickness T3, on a bottom surface of the contact conductive layer 186. The first thickness T1 may be smaller than the third thickness T3, and the third thickness T3 may be smaller than the second thickness T2. The first thickness T1 may be about 1 nm to 2 nm, the second thickness T2 may be about 2 nm to 7 nm, and the third thickness T3 may be about 2 nm to 3 nm. A ratio of the second thickness T2 to the first thickness T 1 may be in a range of about 1 to about 7. The second thickness T2 may be greater than a thickness of the metal-semiconductor compound layer 182.

According to one or more embodiments, the contact plug 180 may include the liner conductive layer 184 instead of a diffusion barrier layer, also referred to as a barrier metal layer, such as TiN, Ta, TaN, WC, TiSiN, or the like for at least the same purpose of preventing or reducing metal atom diffusion into the interlayer insulating layer 199 which degrades device performance. The liner conductive layer 184 may be formed of a relatively lower resistance material than the above materials for the diffusion barrier layer, to improve electrical characteristics of the contact plug 180 connected to the source/drain region 150. For example, by forming the liner conductive layer 184 including at least one of tungsten (W), molybdenum (Mo), etc. without including nitride (N), titanium (Ti) or tantalum (Ta) forming the diffusion barrier layer, as described above, contact resistance of the contact plug 180 including the liner conductive layer 184 may be reduced to improve at least connection performance. Further, the metal elements such as tungsten (W), molybdenum (Mo), etc. forming the liner conductive layer 184 may have lower diffusivity into the interlayer insulating layer 199, so that no diffusion barrier layer may be required.

As described above, the contact plug 180 may include at least three distinct layers which are the metal-semiconductor compound layer 182, the liner conductive layer 184, and the contact conductive layer 186. These three layers may be formed at different steps or different processes, and thus, a connection surface, an interface or a junction may be formed therebetween when viewed through, for example, cross-sectional transmission electron microscopy (TEM) or scanning electron microscope (SEM) even if the liner conductive layer 184 and the contact conductive layer 186 are formed of the same metal material.

An interconnection structure such as a contact plug may be further disposed on the gate electrode 165, and an interconnection structure such as an interconnection line connected to the contact plugs 180 may be further disposed on the contact plugs 180.

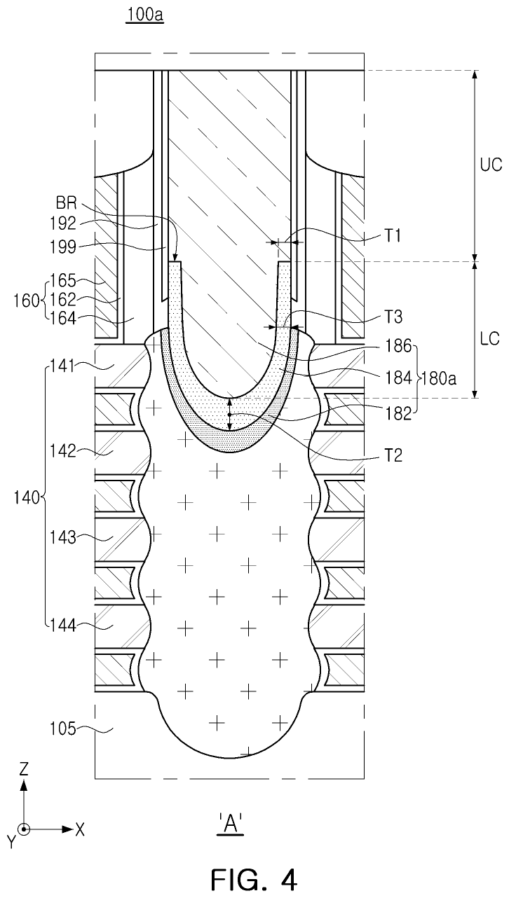

FIG. 4 is a cross-sectional view illustrating a semiconductor device according to one or more embodiments. FIG. 4 illustrates a region corresponding to FIG. 3.

In a description of embodiments below, any description overlapping the description described above with reference to FIGS. 1 to 3 will be omitted. Referring to FIG. 4, in a semiconductor device 100a, a structure of a liner conductive layer 184 of contact plugs 180a may be different from that in the embodiment of FIG. 3.

Referring to FIG. 4, a contact conductive layer 186 may include a lower region LC in which a side surface of the liner conductive layer 184 extending along a side surface of the contact conductive layer 186 is formed, and an upper region UC on the lower region LC. The liner conductive layer 184 may not be disposed in the upper region UC of the contact conductive layer 186, and the liner conductive layer 184 may be formed in the lower region LC of the contact conductive layer 186.

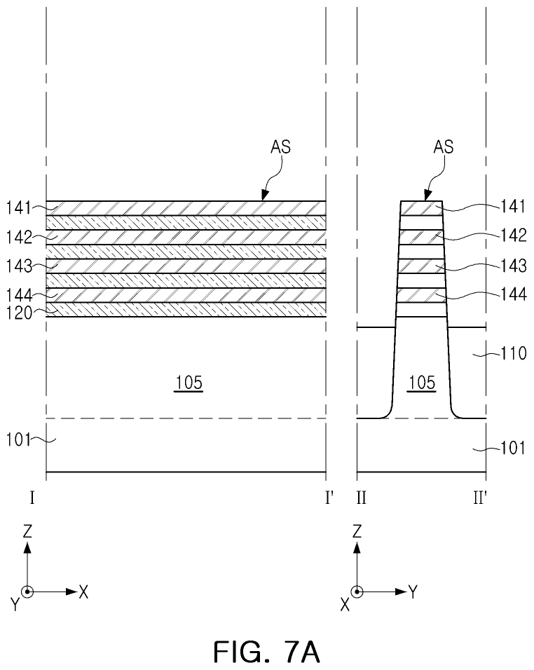

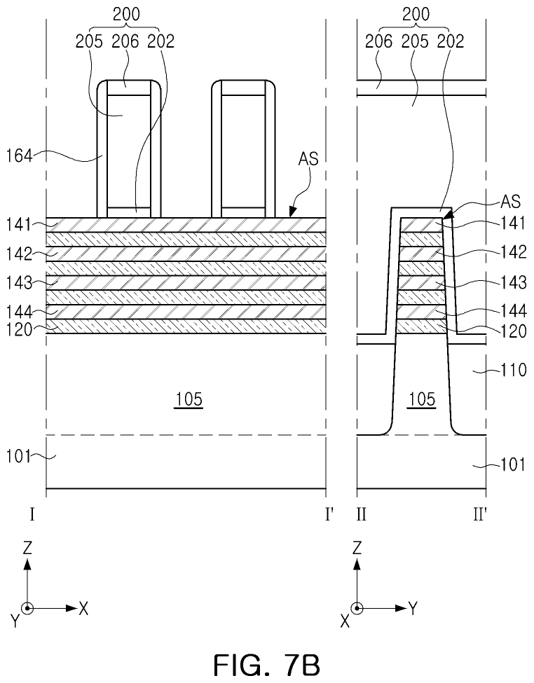

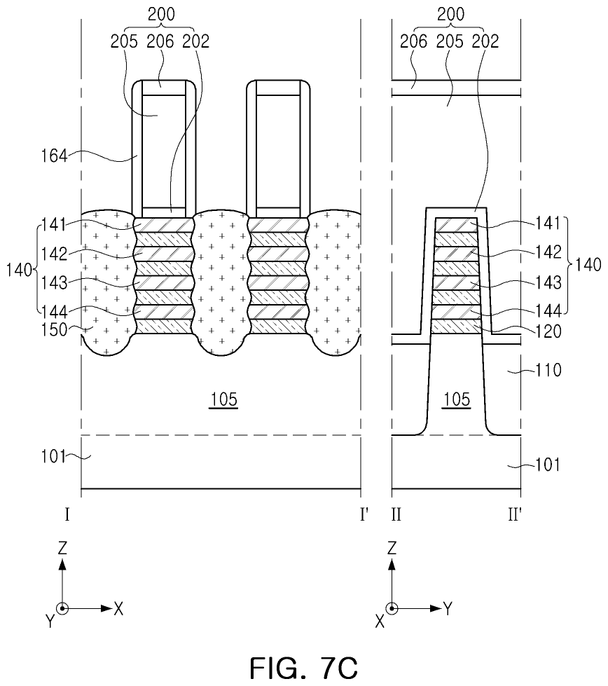

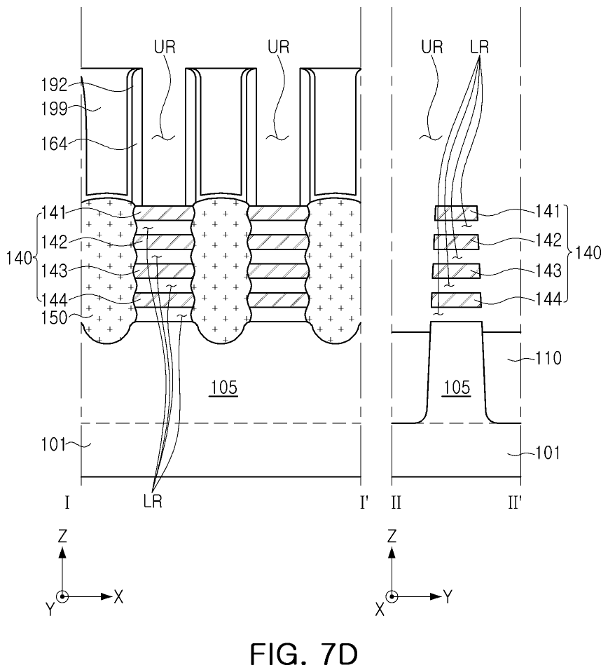

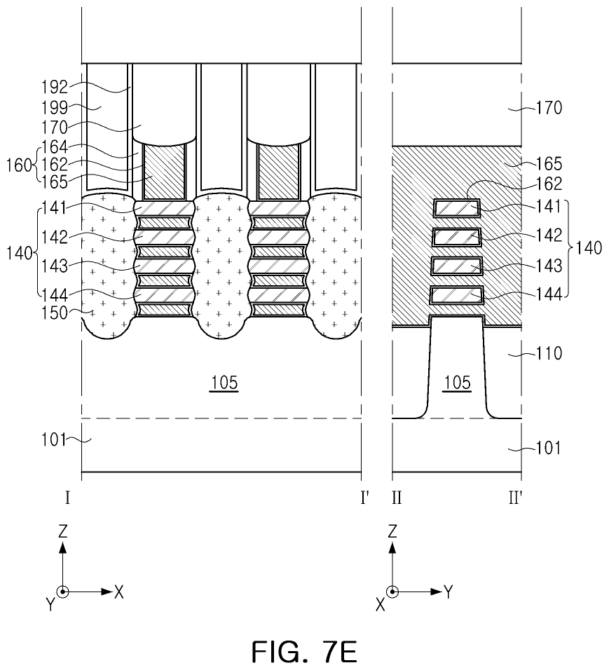

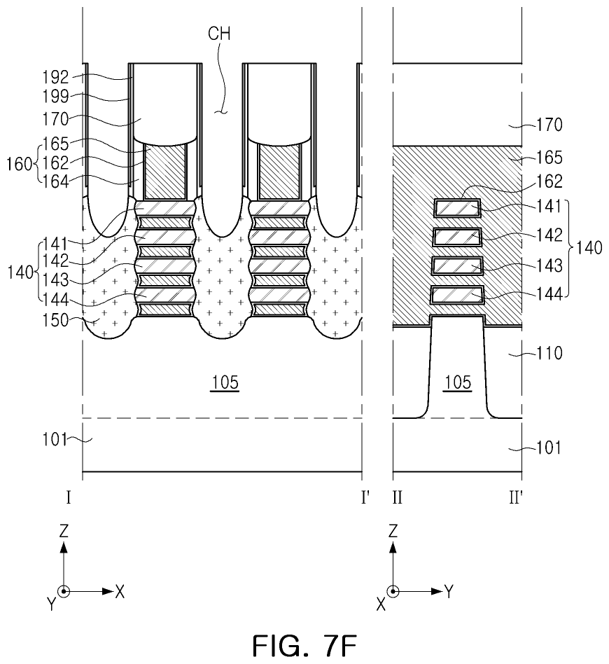

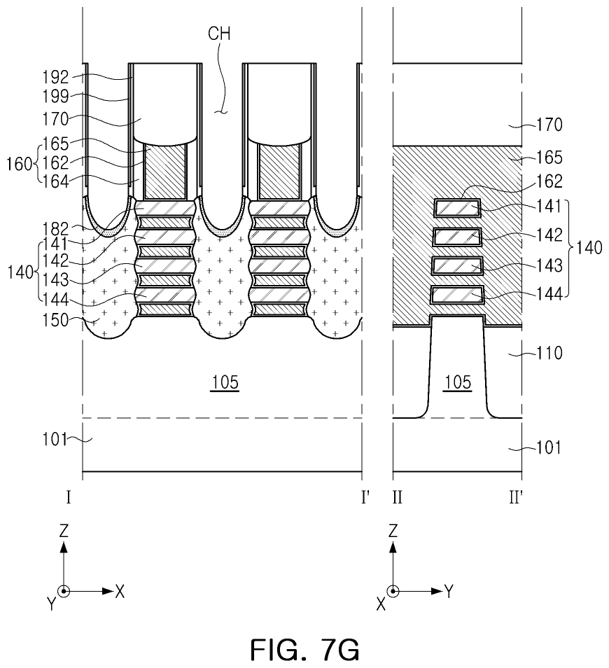

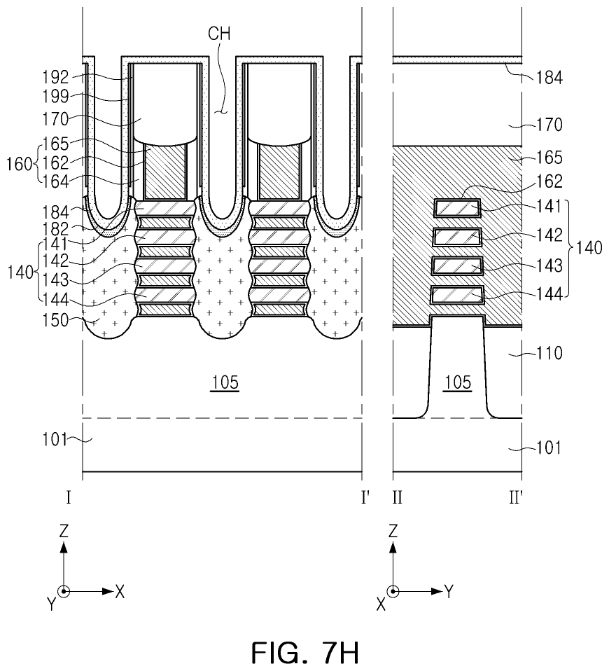

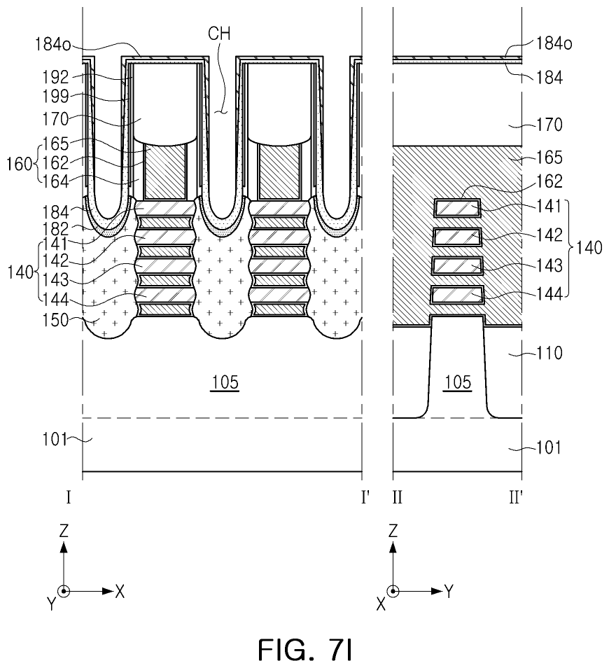

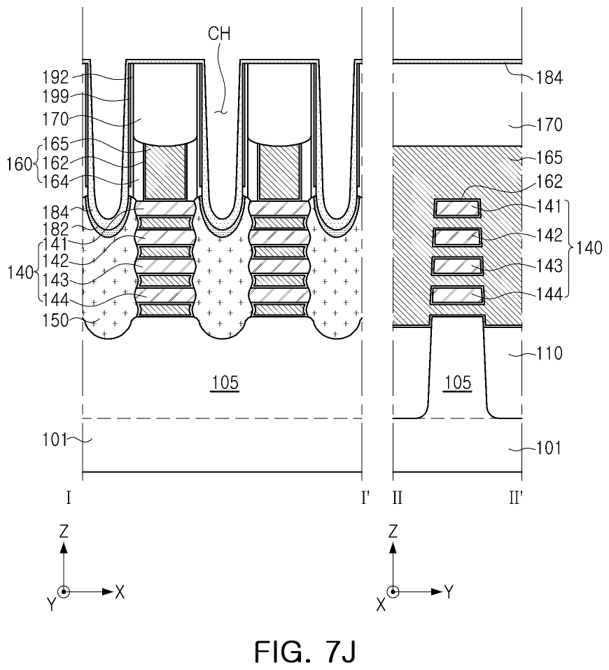

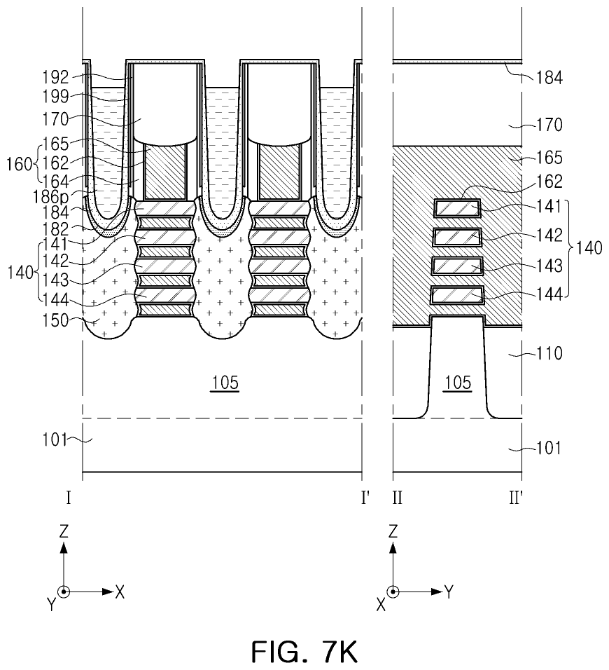

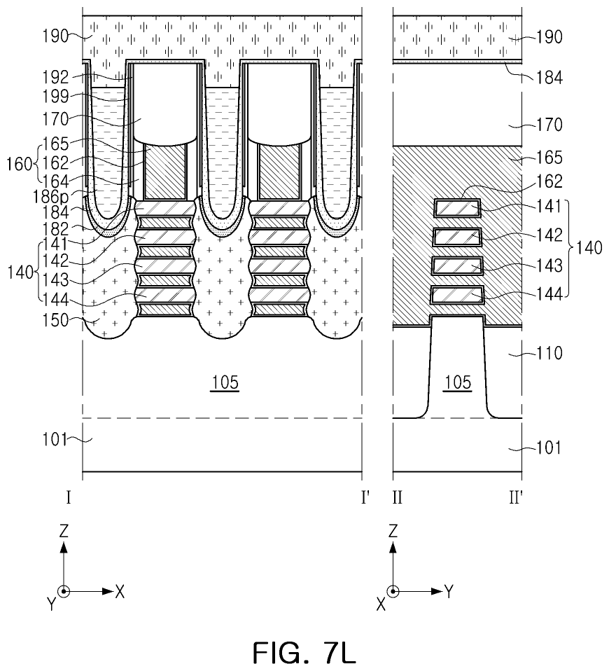

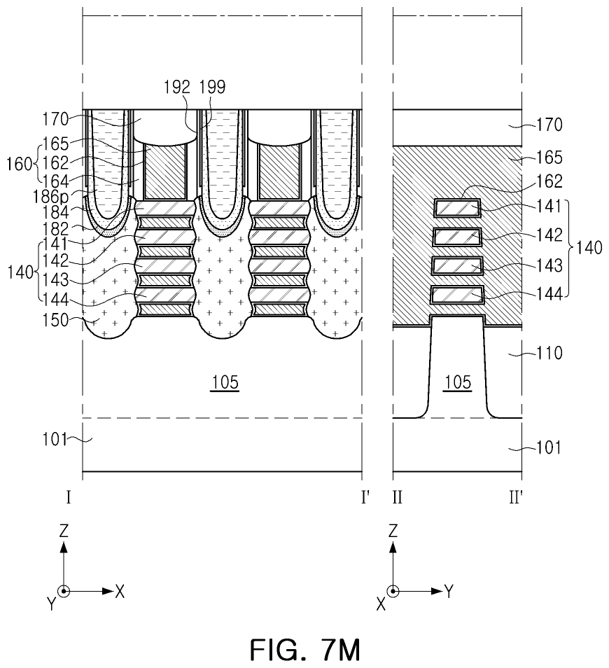

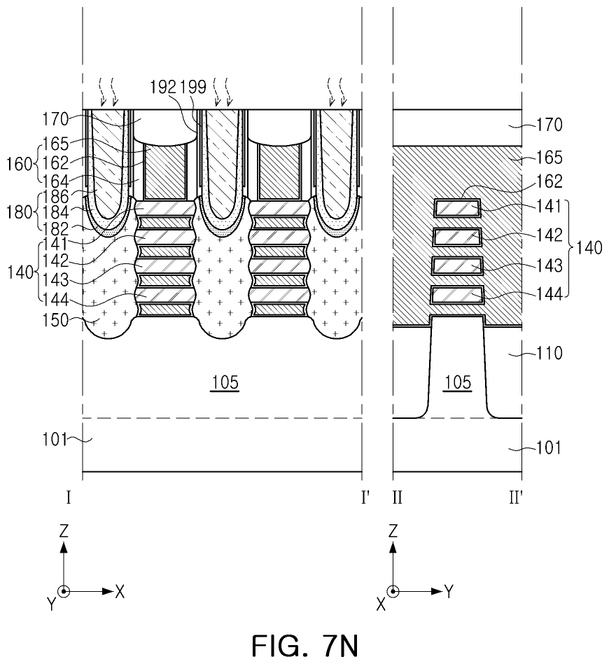

The contact conductive layer 186 may include a bent portion BR of which a width is changed discontinuously between the lower region LC and the upper region UC. The bent portion BR may be at a height of about ⅓ or more and ½ or less of a total height of the contact plugs 180a, but is not limited thereto. A position of the bent portion may change depending on a degree of oxidation of the liner conductive layer 184 (see FIGS. 7I and 7J). When the position of the bent portion BR is about ⅓ or less of the total height of the contact plugs 180a, damage to lower contact may occur during a process of selectively removing an oxidized portion of the liner conductive layer 184.

A side region of the liner conductive layer 184 extending along the side surface of the contact conductive layer 186 may have a thickness increasing toward a source/drain region. The liner conductive layer 184 may have a first thickness T1 and a third thickness T3 on the side surface of the contact conductive layer 186, and may have a second thickness T2, greater than the first thickness T1 and the third thickness T3, on a bottom surface of the contact conductive layer 186. The first thickness T1 may be smaller than the third thickness T3, and the third thickness T3 may be smaller than the second thickness T2.

The first thickness T1 may be about 1 nm to 2 nm, the second thickness T2 may be about 2 nm to 7 nm, and the third thickness T3 may be about 2 nm to 3 nm. A ratio of the second thickness T2 to the first thickness T1 may be in a range of about 1 to about 7. The second thickness T2 may be greater than a thickness of a metal-semiconductor compound layer 182. Such a semiconductor device 100a may be additionally disposed in one region of the semiconductor device of other embodiments.

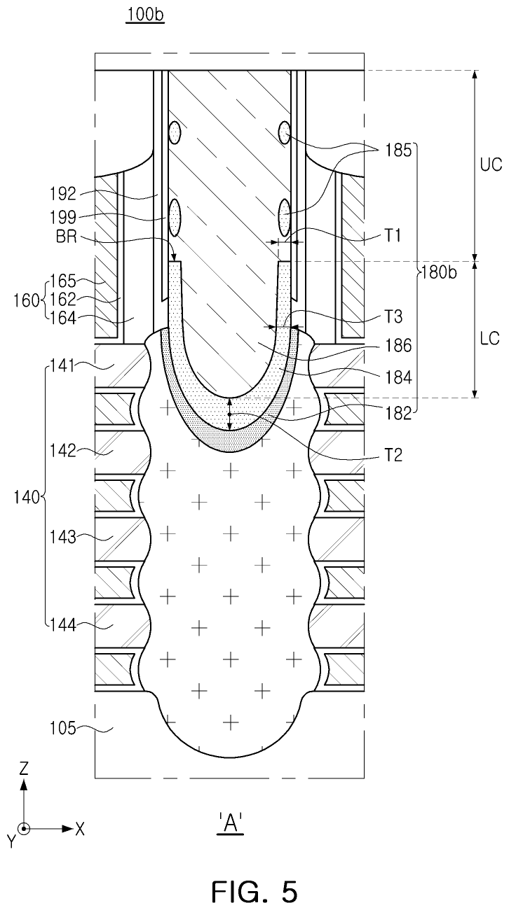

FIG. 5 is a cross-sectional view illustrating a semiconductor device according to one or more embodiments. FIG. 5 illustrates a region corresponding to FIG. 3.

Referring to FIG. 5, in a semiconductor device 100b, a structure of a liner conductive layer 184 of contact plugs 180b may be different from that in the embodiments of FIGS. 3 and 4.

Referring to FIG. 5, a contact conductive layer 186 may include a lower region LC in which a side surface of the liner conductive layer 184 extending along a side surface of the contact conductive layer 186 is formed, and an upper region UC on the lower region LC. The contact conductive layer 186 may include a bent portion BR of which a width is changed discontinuously between the lower region LC and the upper region UC.

The bent portion BR may be at a height of about ⅓ or more and ½ or less of a total height of the contact plugs 180b, but is not limited thereto. A position of the bent portion may change depending on a degree of oxidation of the liner conductive layer 184 (see FIGS. 7I and 7J). When the position of the bent portion BR is about ⅓ or less of the total height of the contact plugs 180b, damage to lower contact may occur during the process of selectively removing the oxidized liner conductive layer 184.

Referring to FIG. 5, in the semiconductor device 100b, the contact plugs 180b may further include upper liner conductive layers 185 formed on a side surface of the contact conductive layer 186 in the upper region UC. The upper liner conductive layers 185 may have different positions depending on a degree of oxidation of the liner conductive layer 184 (see FIGS. 7I and 7J). The upper liner conductive layers 185 may be formed to be non-uniformly and vertically spaced apart on a side surface of the contact conductive layer 186 in the upper region UC, and there may be no limitation on the number of upper liner conductive layers 185 formed. Such a semiconductor device 100b may be additionally disposed in one region of the semiconductor device of other embodiments.

The same description as that referring to FIG. 4 may be applied to the first to third thicknesses.

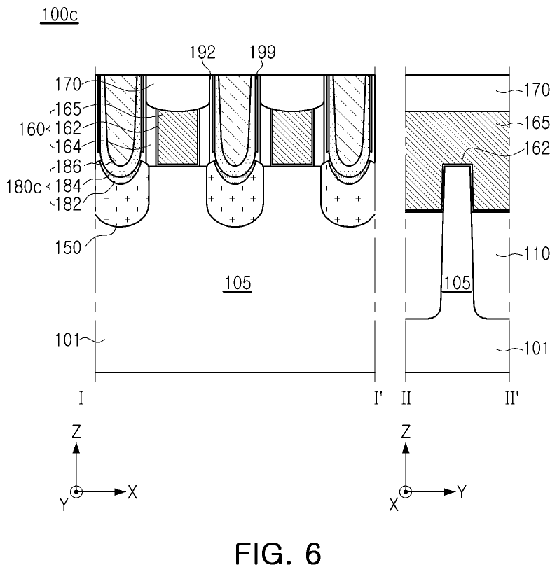

FIG. 6 is a cross-sectional view illustrating a semiconductor device according to one or more embodiments. FIG. 6 illustrates a region corresponding to FIG. 2.

Referring to FIG. 6, a semiconductor device 100c may not include the channel structures 140 of the embodiments of FIGS. 1 to 3, and accordingly, arrangement of gate structures 160 may be different from those in the embodiments described above. The semiconductor device 100c may include FinFETs not including a channel layer like the channel layers 141, 142, 143, and 144.

In the semiconductor device 100c, a channel region of transistors may be limited to an active region 105 having a fin structure, which may be an active structure. In addition, separate channel layers may not be interposed in gate electrodes 165. Therefore, source/drain regions 150 may not have curvatures corresponding to the gate structure 160 and channel layers on the side surfaces.

In addition, a description of a structure of contact plugs 180c or the like may be applied equally to the description in the embodiments of FIGS. 1 to 3. Such a semiconductor device 100c may be additionally disposed in one region of semiconductor devices of other embodiments.

FIGS. 7A to 7N are views illustrating a process sequence illustrating a method of manufacturing a semiconductor device according to one or more embodiments. FIGS. 7A to 7N illustrate an embodiment of a manufacturing method for manufacturing the semiconductor device of FIG. 2.

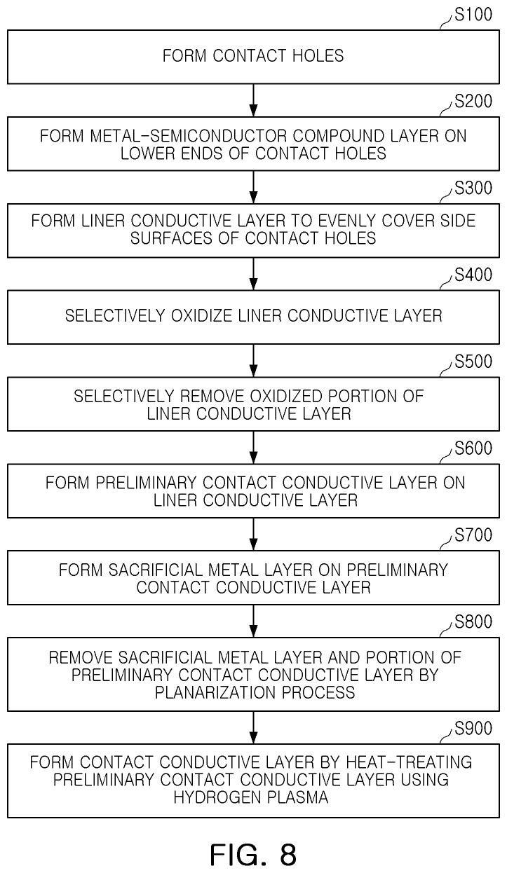

FIG. 8 is a schematic process flow diagram illustrating a method of manufacturing a semiconductor device according to one or more embodiments.

Referring to FIG. 7A, sacrificial layers 120 and first to fourth channel layers 141, 142, 143, and 144 may be alternately stacked on a substrate 101, and the sacrificial layers 120, the first to fourth channel layers 141, 142, 143, and 144, and the substrate 101 may be partially removed, to form an active structure AS including an active region 105, and to form a device isolation layer 110.

The sacrificial layers 120 may be layers to be replaced with gate dielectric layers 162 and gate electrodes 165 below the first channel layer 141 by a subsequent process, as illustrated in FIG. 2. The sacrificial layers 120 may be formed of a material having etching selectivity with respect to the first to fourth channel layers 141, 142, 143, and 144, respectively. The first to fourth channel layers 141, 142, 143, and 144 may include a different material from the sacrificial layers 120. The sacrificial layers 120 and the first to fourth channel layers 141, 142, 143, and 144 may include a semiconductor material including, for example, at least one of silicon (Si), silicon germanium (SiGe), or germanium (Ge), but may include different materials, and may or may not include impurities. For example, the sacrificial layers 120 may include silicon germanium (SiGe), and the first to fourth channel layers 141, 142, 143, and 144 may include silicon (Si).

The sacrificial layers 120 and the first to fourth channel layers 141, 142, 143, and 144 may be formed by performing an epitaxial growth process from the stacked structure. The number of layers of the channel layers alternately stacked with the sacrificial layers 120 may be variously changed according to embodiments.

The active structure AS may include the active region 105, the sacrificial layers 120, and the first to fourth channel layers 141, 142, 143, and 144. The active structure AS may be formed in a linear shape extending in one direction, for example, the X-direction, and may be formed to be spaced apart from an adjacent active structure in the Y-direction. Side surfaces of the active structure AS in the Y-direction may be coplanar, and may be on a straight line.

In a region in which a portion of the active region 105, a portion of the sacrificial layers 120, and a portion of the first to fourth channel layers 141, 142, 143, and 144 are removed, an insulating material may be filled therein, and then the device isolation layer 110 may be formed by removing a portion of the insulating material such that the active region 105 protrudes. An upper surface of the device isolation layer 110 may be formed lower than an upper surface of the active region 105.

Referring to FIG. 7B, sacrificial gate structures 200 and gate spacer layers 164 may be formed on the active structure AS.

Each of the sacrificial gate structures 200 may be a sacrificial structure formed in a region in which the gate dielectric layers 162 and the gate electrodes 165 are disposed on the channel structure 140 by a subsequent process, as illustrated in FIG. 2. The sacrificial gate structures 200 may have a linear shape extending in one direction while intersecting the active structure. The sacrificial gate structures 200 may extend, for example, in the Y-direction. Each of the sacrificial gate structures 200 may include first and second sacrificial gate layers 202 and 205 and a mask pattern layer 206, sequentially stacked. The first and second sacrificial gate layers 202 and 205 may be patterned using the mask pattern layer 206.

The first and second sacrificial gate layers 202 and 205 may be an insulating layer and a conductive layer, respectively, but are not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

Gate spacer layers 164 may be formed on both sidewalls of the sacrificial gate structures 200. The gate spacer layers 164 may be formed of a low-κ material, and may include, for example, at least one of SiO, SiN, SiCN, SiOC, SiON, or SiOCN.

Referring to FIG. 7C, the active structure AS exposed from the sacrificial gate structures 200 may be partially removed to form recess regions, and source/drain regions 150 may be formed in the recess regions.

Using the sacrificial gate structures 200 and the gate spacer layers 164 as masks, a portion of the exposed sacrificial layers 120 and a portion of the first to fourth channel layers 141, 142, 143, and 144 may be removed to form recess regions RC. As a result, the first to fourth channel layers 141, 142, 143, and 144 may form channel structures 140 having a limited length in the X-direction.

The source/drain regions 150 may be formed in the recess regions. The source/drain regions 150 may be formed by growing, for example, from side surfaces of the active region 105 and side surfaces of the channel structures 140 by a selective epitaxial process. The source/drain regions 150 may include impurities by in-situ doping, and may include a plurality of layers having different doping elements and/or different doping concentrations.

Referring to FIG. 7D, insulating liner layers 192 and an interlayer insulating layer 199 may be formed, and the sacrificial gate structures 200 and the sacrificial layers 120 may be removed.

The insulating liner layers 192 may be formed to extend along side surfaces of the sacrificial gate structures 200 and upper surfaces of the source/drain regions 150. The insulating liner layers 192 may include a relatively hard and low dielectric constant material. For example, the insulating liner layers 192 may include a harder material than the interlayer insulating layer 199, and may include, for example, SiCN. The interlayer insulating layer 199 may be formed to fill a space between the sacrificial gate structures 200 on the insulating liner layers 192. The insulating liner layers 192 and the interlayer insulating layer 199 may be formed to expose the mask pattern layers 206 using a planarization process.

The sacrificial gate structures 200 and the sacrificial layers 120 may be selectively removed relative to the gate spacer layers 164, the insulating liner layers 192, and the channel structures 140. First, the sacrificial gate structures 200 may be removed to form upper gap regions UR, and then the sacrificial layers 120 exposed through the upper gap regions UR may be removed to form lower gap regions LR. For example, when the sacrificial layers 120 include silicon germanium (SiGe) and the channel structures 140 include silicon (Si), the sacrificial layers 120 may be selectively removed with respect to the channel structures 140 by performing a wet etching process.

Referring to FIG. 7E, gate structures 160 and gate capping layers 170 may be formed.

The gate structures 160 may be formed to fill the upper gap regions UR and the lower gap regions LR. The gate dielectric layers 162 may be formed to be conformally on inner surfaces of the upper gap regions UR and inner surfaces of the lower gap regions LR. After the gate electrode 165 is formed to fill the upper gap regions UR and the lower gap regions LR, the gate dielectric layers 162 and the gate spacer layers 164 may be removed from the upper gap regions UR to a predetermined depth. As a result, the gate structures 160 respectively including the gate dielectric layers 162, the gate electrode 165, and the gate spacer layers 164 may be formed.

The gate capping layers 170 may be formed by filling an insulating material in regions from which respective portions of the gate electrode 165, the gate dielectric layers 162, and the gate spacer layers 164 are removed, and performing a planarization process. Relative thickness of the gate capping layers 170 and shapes of lower surfaces may be variously changed according to the embodiments.

Referring to FIG. 7F together with FIG. 8, the interlayer insulating layer 199, the insulating liner layers 192, and the source/drain regions 150 may be partially removed, respectively, to form contact holes CH (S100).

The contact holes CH may be formed by sequentially etching the interlayer insulating layer 199 and the insulating liner layers 192 from an upper portion in a region in which contact plugs 180 (see FIG. 2) are to be formed, and recessing the exposed source/drain regions 150 from an upper surface. Lower ends of the contact holes may be, for example, at a level between a lower surface of the first channel layer 141 and an upper surface of the third channel layer 143.

Referring to FIG. 7G together with FIG. 8, a metal-semiconductor compound layer 182 may be formed in a region including the lower ends of the contact holes CH (S200).

The metal-semiconductor compound layer 182 may be formed by depositing a metal layer at a relatively high temperature, for example, about 300° C. to about 500° C., and allowing the metal layer to react with the source/drain regions 150. The metal layer may include, for example, titanium (Ti). The metal-semiconductor compound layer 182 may include a metal element and a semiconductor element, and, for example, may include TiSi.

Unlike what may be illustrated in FIG. 7G, the metal-semiconductor compound layer 182 may be formed to protrude from inner side surfaces of the contact holes CH. Therefore, the metal-semiconductor compound layer 182 illustrated in FIGS. 2 to 6 may be formed to protrude inwardly toward the contact conductive layer 186, and a thickness of a liner conductive layer 184 contacting the metal-semiconductor compound layer 182 may be formed unevenly.

Referring to FIG. 7H together with FIG. 8, a liner conductive layer 184 may be formed on the metal-semiconductor compound layer 182 to be on side surfaces of the contact holes CH (S300).

The liner conductive layer 184 may be formed to conformally on side surfaces of the contact holes CH, and may be formed to extend onto the gate capping layers 170. The liner conductive layer 184 may be formed by depositing a metal material. The liner conductive layer 184 may include, for example, tungsten (W) or molybdenum (Mo). A method of depositing the liner conductive layer 184 may change depending on a type of metal of the liner conductive layer 184. The method of depositing the liner conductive layer 184 may include, for example, physical vapor deposition (PVD), atomic layer deposition (ALD), or the like.

For example, when depositing a tungsten metal layer using atomic layer deposition, a tungsten layer may be formed by reacting WCl₅ (tungsten pentachloride) and hydrogen (H₂). As another example, when depositing a molybdenum metal layer using atomic layer deposition, a molybdenum layer may be formed by reacting MoCl₅ (molybdenum pentachloride) or MoO₂Cl₂ (molybdenum dioxydichloride) with hydrogen (H₂).

Referring to FIG. 7I together with FIG. 8, the liner conductive layer 184 formed on the metal-semiconductor compound layer 182 may be selectively oxidized (S400).

A surface of the liner conductive layer 184 formed on the metal-semiconductor compound layer 182 may react with oxygen to form a liner oxide layer 184o. The liner oxide layer 184o may be formed, for example, by oxygen plasma reacting with metal on the surface of the liner conductive layer 184. The liner oxide layer 184o may be formed to extend onto the gate capping layers 170.

During a deposition process of the liner conductive layer 184, the liner conductive layer 184 may be formed to conformally on the side surfaces of the contact holes CH, but an overhang in a protruding shape may be formed in an upper portion of the liner conductive layer 184. To remove the overhang, a process of selectively oxidizing and removing the liner conductive layer 184 may be required. Therefore, the liner conductive layer 184 may be oxidized in a portion including an upper region, and may not be oxidized in a portion including a lower region. The liner oxide layer 184o may be formed in the upper portion of the liner conductive layer 184, and may not be formed in at least a portion of a lower portion of the liner conductive layer 184.

A range of the liner oxide layer 184o formed may change according to embodiments, and for example, may be formed deeper than that illustrated in FIG. 7I in a direction toward the source/drain region 150. A thickness of the liner oxide layer 184o may change according to embodiments, and for example, the liner oxide layer 184o extending along the side surface of the contact holes CH may be sharply or gently reduced in thickness toward the source/drain region 150. Depending on a range or depth of the formed liner oxide layer 184o, the bent portion BR of FIGS. 4 and 5 may be formed, and the upper liner conductive layers 185 of FIG. 5 may be formed when the liner oxide layer 184o is removed in a next step (FIG. 7J).

Referring to FIG. 7J together with FIG. 8, an oxidized portion of the liner conductive layer 184 may be selectively removed (S500). In this case, the oxidized portion of the liner conductive layer 184 may refer to the liner oxide layer 184o of FIG. 7I.

The liner oxide layer 184o may be removed by dry etching using a chlorine (Cl)-based chemical substance. Specifically, the liner oxide layer 184o may be selectively removed using a precursor including WCl₅ (tungsten pentachloride) and/or MoCl₅ (molybdenum pentachloride). Therefore, the oxidized portion of the liner conductive layer 184 may form a structure of the liner conductive layer 184.

A process of selectively removing the oxidized liner conductive layer 184 may be controlled according to pressure in a chamber and dose of the precursor. For example, when a relatively low chamber pressure is used, a range of the liner conductive layer 184 to be removed may be smaller than a case in which a relatively high chamber pressure is used. Therefore, a structure of the liner conductive layer 184 of FIG. 3 may be formed. When a high chamber pressure is used, a range of the liner conductive layer 184 to be removed may be wider, and accordingly, a structure of the liner conductive layer 184 of FIG. 4 may be formed, and the liner conductive layer 184 and the upper liner conductive layers 185 of FIG. 5 may be formed.

When the precursor of the precursor is relatively low, the range of the liner conductive layer 184 to be removed may be smaller than a case in which the precursor of the precursor is relatively high. Therefore, the structure of the liner conductive layer 184 of FIG. 3 may be formed. When the precursor of the precursor is high, the range of the liner conductive layer 184 to be removed may be wide, and accordingly, the structure of the liner conductive layer 184 of FIG. 4 may be formed, and the liner conductive layer 184 and the upper liner conductive layers 185 of FIG. 5 may be formed.

Depending on the range of the liner conductive layer 184 to be removed, the bent portion BR of FIG. 4 and FIG. 5 may be formed, and the upper liner conductive layers 185 of FIG. 5 may be formed. Therefore, the structure of the liner conductive layer 184 of the semiconductor device according to the one or more embodiments of FIG. 3, FIG. 4, and FIG. 5 may be formed.

Referring to FIG. 7K together with FIG. 8, a preliminary contact conductive layer 186p may be formed on the liner conductive layer 184 (S600).

The preliminary contact conductive layer 186p may be formed to at least partially fill the contact holes CH on the liner conductive layer 184. In one or more embodiments, the preliminary contact conductive layer 186p may be formed to extend onto the gate capping layers 170. The preliminary contact conductive layer may include tungsten (W) or molybdenum (Mo). The preliminary contact conductive layer 186p may include grains therein. The grains of the preliminary contact conductive layer 186p may have a size of about 4 nm to 9 nm. Resistivity of the preliminary contact conductive layer 186 p may be in a range of, for example, about 10 μΩcm to about 20 μΩcm.

The preliminary contact conductive layer 186p may be formed by depositing a metal material. The preliminary contact conductive layer 186p may include, for example, tungsten (W) or molybdenum (Mo). A method of depositing the preliminary contact conductive layer 186p may change depending on a type of metal of the preliminary contact conductive layer 186p. The method of depositing the preliminary contact conductive layer 186p may include, for example, atomic layer deposition or chemical vapor deposition (CVD).

When depositing tungsten metal using atomic layer deposition, a tungsten layer may be formed by reacting WCl₅ (tungsten pentachloride) and hydrogen (H₂). When depositing a molybdenum metal layer using atomic layer deposition, a molybdenum layer may be formed by reacting MoCl₅ (molybdenum pentachloride) or MoO₂Cl₂ (molybdenum dioxydichloride) with hydrogen (H₂). When depositing tungsten metal using chemical vapor deposition, a tungsten layer may be formed by reacting WF₆ (tungsten hexafluoride) with hydrogen (H₂).

Referring to FIG. 7L together with FIG. 8, a sacrificial metal layer 190 may be formed on the preliminary contact conductive layer 186p (S700).

The sacrificial metal layer 190 may be formed to fill the contact holes CH on the preliminary contact conductive layer 186p, and may also be formed to extend onto the gate capping layers 170. The sacrificial metal layer 190 may include tungsten (W), molybdenum (Mo), or the like.

Referring to FIG. 7M together with FIG. 8, the sacrificial metal layer 190 and a portion of the preliminary contact conductive layer 186p may be removed using a planarization process (S800).

The sacrificial metal layer 190 may be removed, and a portion of the preliminary contact conductive layer 186p may be removed from an upper surface, using an etching process and/or a planarization process, thereby forming preliminary contact conductive layers 186p separated from each other. In this operation, the gate capping layers 170 may also be partially removed to have a form with a reduced height. During the process, the preliminary contact conductive layer 186p having a desired height may be formed by the sacrificial metal layer 190. The planarization process may cause uneven distribution. To prevent this, the sacrificial metal layer 190 may be formed to minimize unevenness that may occur during the planarization process, and the preliminary contact conductive layer 186p having a desired height may be formed.

Referring to FIG. 7N together with FIG. 8, a contact conductive layer 186 may be formed by heat-treating the preliminary contact conductive layer 186p using hydrogen plasma (S900).

Specifically, the contact conductive layer 186 may be formed by rearranging atoms in metal by heat-treating at a temperature of about 300° C. to about 500° C.

The contact conductive layer 186 may include grains therein, and a size of each of the grains may be about 10 nm to 12 nm. The size of each of the grains of the contact conductive layer 186 may be larger than that of the preliminary contact conductive layer 186p by heat-treatment using hydrogen plasma. Therefore, the contact conductive layer 186 may have a reduced grain boundary, which facilitates carrier mobility, thereby reducing resistivity. Resistivity of the contact conductive layer 186 may be, for example, in a range of about 9 μΩcm to about 18 μΩcm.

According to an embodiment, by optimizing a structure of a contact plug connected to a source/drain region, a semiconductor device having improved electrical characteristics may be provided, and a method for manufacturing a semiconductor device having reduced process difficulty and reduced process cost may be provided.

While one or more embodiments have been illustrated and described above, it will be apparent to those skilled in the art that modifications and variations could be made without departing from the scope of the present inventive concept as defined by the appended claims.

What is claimed is:

1. A method of manufacturing a semiconductor device, comprising:
forming a source/drain region;
forming an interlayer insulating layer on the source/drain region;
forming a contact hole by removing at least a portion of the interlayer insulating layer to expose the source/drain region;
forming a metal-semiconductor compound layer in the contact hole to be connected to the source/drain region;
forming a liner conductive layer on the metal-semiconductor compound layer; and
oxidizing the liner conductive layer;
removing an oxidized portion of the liner conductive layer;
forming a preliminary contact conductive layer on the liner conductive layer;
forming a sacrificial metal layer on the preliminary contact conductive layer;
removing the sacrificial metal layer and a portion of the preliminary contact conductive layer using a planarization process; and
forming a contact conductive layer by heat treating the preliminary contact conductive layer using hydrogen plasma.

2. The method of claim 1, wherein the liner conductive layer has a thickness which varies along an inner profile of the contact hole.

3. The method of claim 2, wherein a thickness of the liner conductive layer is greater than a thickness of the metal-semiconductor compound layer.

4. The method of claim 1, wherein nitride (N) is not included between the contact conductive layer and the interlayer insulating layer.

5. The method of claim 1, wherein the liner conductive layer does not comprise titanium (Ti) or tantalum (Ta).

6. The method of claim 1, wherein a thickness of the liner conductive layer increases toward the source/drain region.

7. The method of claim 1, wherein the contact conductive layer comprises a lower region in which a side surface of the liner conductive layer is formed along a side surface of the contact conductive layer, and an upper region on the lower region, and
wherein the contact conductive layer has a bent portion of which a width is discontinuously changed between the lower region and the upper region.

8. The method of claim 7, wherein the contact conductive layer further comprises an upper liner conductive layer on the side surface of the contact conductive layer in the upper region.

9. The method of claim 7, wherein the bent portion is at a height of ⅓ or more and ½ or less of a total height of the contact holes.

10. A method of manufacturing a semiconductor device, comprising:
forming a semiconductor region on a substrate and forming an interlayer insulating layer on the semiconductor region;
removing a portion of the interlayer insulating layer to form a contact hole exposing the semiconductor region;
forming a metal-semiconductor compound layer on a lower end of the contact hole to be connected to the semiconductor region;
forming a liner conductive layer on the metal-semiconductor compound layer;
forming a preliminary contact conductive layer on the liner conductive layer; and
forming a contact conductive layer by heat-treating the preliminary contact conductive layer such that a size of a crystal grain of the contact conductive layer is greater than a size of a crystal grain of the preliminary contact conductive layer.

11. The method of claim 10, further comprising:
oxidizing a portion of the liner conductive layer such that a portion of the liner conductive layer comprising an upper region is oxidized, and a portion of the liner conductive layer comprising a lower region is not oxidized; and
removing an oxidized portion of the liner conductive layer prior to the forming the preliminary contact layer on the liner conducive layer.

12. The method of claim 10, wherein the heat-treating the preliminary contact layer is performed using hydrogen plasma.

13. The method of claim 10, wherein the liner conductive layer comprises at least one of tungsten (W) or molybdenum (Mo), and
wherein the contact conductive layer comprises at least one of tungsten (W) or molybdenum (Mo).

14. A method of manufacturing a semiconductor device, comprising:
forming a source/drain region and an interlayer insulating layer on the source/drain region;
removing a portion of the interlayer insulating layer to form a contact hole exposing the source/drain region;
forming a metal-semiconductor compound layer on a lower end of the contact hole;
forming a liner conductive layer on the metal-semiconductor compound layer;
removing a portion of the liner conductive layer;
forming a preliminary contact conductive layer on the liner conductive layer;
forming a sacrificial metal layer on the preliminary contact conductive layer;
removing the sacrificial metal layer and a portion of the preliminary contact conductive layer using a planarization process; and
heat-treating the preliminary contact conductive layer using hydrogen plasma to form a contact conductive layer,
wherein the liner conductive layer is formed such that the liner conductive layer has a first thickness on a side surface of the contact conductive layer, and a second thickness, greater than the first thickness, on a bottom surface of the contact conductive layer.

15. The method of claim 14, wherein the removing a portion of the liner conductive layer comprise:
oxidizing the liner conductive layer formed on the metal-semiconductor compound layer; and
removing an oxidized portion of the liner conductive layer.

16. The method of claim 14, wherein the liner conductive layer does not comprise nitride (N), and comprises at least one of tungsten (W) or molybdenum (Mo).

17. The method of claim 14, wherein the contact conductive layer comprises at least one of tungsten (W) or molybdenum (Mo).

18. The method of claim 14, wherein a thickness of the metal-semiconductor compound layer is in a range of about 1 nm to about 4 nm.

19. The method of claim 14, wherein a ratio of resistivity of the liner conductive layer to resistivity of the contact conductive layer is in a range of about 0.45 to about 1.8.

20. The method of claim 14, wherein a connection surface, an interface or a junction is formed between the metal-semiconductor compound layer, the liner conductive layer, and the contact conductive layer.
